(19) United States
(12) Patent Application Publication
(10) Pub. No.: US 2021/0047723 A1
(43) Pub. Date: Feb. 18, 2021

(54) Chrome-Look PVD Layer With Improved Adhesion

(71) Applicant: OERLIKON SURFACE SOLUTIONS AG, PFÄFFIKON, Pfaffikon (CH)

(72) Inventor: Arnd Mueller, Malans (CH)

(21) Appl. No.: 17/048,216

(22) PCT Filed: Apr. 18, 2019
(86) PCT No.: PCT/EP2019/000126

§ 371 Date: Oct. 16, 2020

(30) Foreign Application Priority Data
Apr. 19, 2018 (CH) CH00506/18

(51) Int. Cl. C23C 14/20; C23C 14/00; C23C 14/02; C23C 14/58

(52) U.S. Cl. CPC C23C 14/205; C23C 14/58; C23C 14/024; C23C 14/0015

(57) ABSTRACT

A novel physical vapor deposition (PVD) layer structure for chrome-look coatings on plastic substrates shows very good adhesion. The PVD coating is embedded in an organic UV cured base coat applied to the substrate prior to PVD coating and a similar organic UV cured top coat to protect the PVD coating and to adjust the gloss level. The novel PVD coating structure consists of different metallic layers such as i.e. chromium, zirconium and aluminum and a new adhesion layer consisting of silicon monoxide (SiO) and silicon.

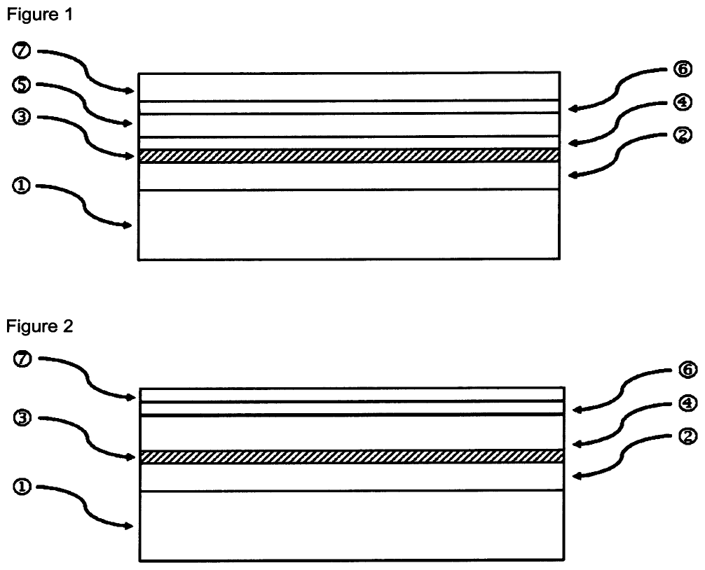

Chrome plating has been a common way to manufacture shiny surfaces on plastic parts. An alternative to this environmentally harmful technique is a physical vapor deposition (PVD) process to obtain a similar effect on plastic substrates by i.e. sputtering or evaporating thin metallic layers onto the substrates. Since these PVD coatings are significantly thinner than traditional chrome plating coatings in some cases an additional base coat between substrate and PVD layer is required to level imperfections of the, in most cases injection molded, plastic parts. In addition, a top coat may be applied to protect the thin metallic coating and to adjust the gloss level of the coating system.

Adhesion of the PVD coating towards the substrate or the organic base coat is always an issue and needs to be addressed. Typically a plasma treatment prior to PVD process is carried out to clean and activate the surface but this might not be sufficient to enable the part to withstand the demanding long term stability requirements of the automotive industry.

A pure PVD chromium layer also tends to crack at a certain coating thickness due to its high tensile stress. This improves the adhesion but is still unwanted due to the bad optical appearance of this effect. To avoid cracking of the chrome-looking PVD layer and also improve adhesion a multilayer system can be used, which reduces the intrinsic stress of the complete PVD coating system.

It is also known that the adding of oxygen gas to an argon gas based sputter process can produce well adhering Chromium(III)oxide (Cr2O3).

The present invention describes a new PVD layer structure that significantly improves adhesion of PVD layers embedded in UV cured organic lacquers on plastic substrates by using the metalloide silicon, deposited in a low oxygen partial pressure atmosphere to achieve siliconmonoxide (SiO) as an adhesion promoting layer.

From optical coatings on polymethylmethacrylates (PMMA) it is known that a thin silicon monoxide (SiO) layer of only a few nanometers in thickness can improve adhesion of dielectric antireflection coatings consisting of low refractive silicon dioxide (SiO2) and high refractive index titanium dioxide (TiO2) significantly. This is probably due to the protection of the PMMA by a shielding of UV light by the non-transparent SiO layer. Solid SiO is e-beam evaporated from a crucible and deposited on the PMMA. Especially the UV light from the e-beam gun is blocked but the light transparency in the visible range is barely affected.

Surprisingly the inventors found that such a SiO layer also improves the adhesion of metallic layers on various organic substrates drastically. Since the light transparency is not an issue for chrome-looking parts the thickness of the SiO layer is not limited to some few nanometers in that case. For semi-transparent metallic coatings (so-called translux coatings) with an even thinner PVD coating the SiO layer can be made thin enough in a way that the light transmission is not affected significantly.

A plastic substrate (i.e. ABS, PC/ABS, PC) is coated with an organic base coat and the lacquer is cured by means of UV light. After this the substrate is transferred into vacuum and pre-treated with a plasma.

After this plasma treatment with Argon or a mixture of Argon and reactive gases like oxygen and nitrogen an SiO adhesion layer is deposited onto the surface. This can be for example done by sputtering pure silicon in an oxygen atmosphere or by sputtering a SiO target. When using pure silicon the oxygen flow is reduced after the deposition of the SiO layer and the silicon is sputtered in pure Argon atmosphere to prevent the target from poisoning.

On top of the adhesion layer additional metallic or metal-oxy-nitrides may be applied to generate different colors. Finally the substrate is transferred back to atmosphere and a UV curable top coat lacquer is applied in the same way as the base coat. The following drawings show some typical examples of layer structures containing the new SiO adhesion layer.

A coated plastic component was disclosed with a plastic substrate and a coating on the plastic substrate to provide for a metallic look. The coating comprises a metallic layer and an adhesion layer between the metallic layer and the plastic substrate where the adhesion layer comprises silicon monoxide to promote adhesion between the metallic layer and an organic material.

The organic material can be the plastic substrate or the organic material can be an organic base coat layer between the plastic substrate and the adhesion layer.

It is possible that on the coating there is a transparent organic top coat layer.

The coating can be a PVD coating.

The coating may comprise a silicon layer which is coated on top of the adhesion layer and preferably the silicon monoxide layer does not form a discrete interface to the silicon layer but forms a gradient with decreasing amount of oxygen.

The coating can comprise different metallic layers, preferably chromium and/or zirconium and/or aluminum and preferably comprises silicon

### REFERENCES

1 plastic substrate

2 UV cured base coat

3 SiO silicon monoxide layer

4 Si silicon layer

5 Zr zirconium layer

6 Cr chromium layer

7 UV cured transparent top coat

1. A coated plastic component with a plastic substrate and a coating on the plastic substrate to provide for a chrome-look, characterized in that the coating comprises a metallic layer and an adhesion layer between the metallic layer and the plastic substrate, where the adhesion layer comprises silicon monoxide to promote adhesion between the metallic layer and an organic base coat layer, wherein the organic base coat layer is a lacquer cured by means of UV light.

2. The coated plastic component according to claim 1, characterized in that on the coating there is an organic transparent top coat layer.

3. The coated plastic component according to claim 2, characterized in that the organic top coat layer is a UV curable layer.

4. The coated plastic component according to claim 3, characterized in that the UV curable layer is applied the same way as the base coat layer.

5. The coated plastic component according to claim 1, characterized in that the coating is a PVD coating.

6. The coated plastic component according to claim 1, characterized in that the coating comprises a silicon layer which is coated on top of the adhesion layer.

7. The coated plastic component according to claim 1, characterized in that the coating comprises different metallic layers.

8. The coated plastic component according to claim 6, characterized in that the adhesion layer comprising silicon monoxide does not form a discrete interface to the silicon layer but forms a gradient with decreasing amount of oxygen.

9. The coated plastic component according to claim 7, characterized in that the different metallic layers comprise chromium, zirconium and/or aluminum layers.

10. The coated plastic component according to claim 9, characterized in that the different metallic layers comprise a silicon layer.
